(19) United States
(12) Patent Application Publication
(10) Pub. No.: US 2008/0296593 A1
(43) Pub. Date: Dec. 4, 2008

(54) Silicon Light Emitting Device

(76) Inventors: Nae Man Park, Daejeon-city (KR); Tae Youb Kim, Seoul (KR); Gun Yong Sung, Daejeon-city (KR)

Correspondence Address: RABIN & Berdo, PC, 1101 14TH STREET, NW, SUITE 500, WASHINGTON, DC, 20005, US

(21) Appl. No.: 12/096,610

(22) PCT Filed: Jun. 16, 2006
(86) PCT No.: PCT/KR2006/002313

§ 371 Date: Jun. 8, 2008

(30) Foreign Application Priority Data
Dec. 8, 2005 (KR) 10-2005-0119464
Feb. 15, 2006 (KR) 10-2006-0014684

(51) Int. Cl. H01L 33/00

(52) U.S. Cl. 257/89; 257/E33.001

(57) ABSTRACT

Provided is a highly-efficient silicon light emitting device including an improved structure by which more light of the light emitted toward the lateral side of the light emitting device is emitted toward the front side thereof than conventional light emitting devices so as to improve the brightness. The silicon light emitting device includes a substrate, a plurality of light emitting structures formed on the substrate, each of the light emitting structures comprising an active layer, and a metal electrode comprising a lower metal electrode formed below the substrate and an upper metal electrode formed on the light emitting structures. The light emitting structures have column shapes whose vertical cross-sections are inverse trapezoid.

### TECHNICAL FIELD

The present invention relates to a silicon semiconductor device, and more particularly, a silicon light emitting device which uses a silicon fine structure as an active layer and has a new structure that is capable of increasing the optical extraction efficiency.

### BACKGROUND ART

Silicon light emitting devices, for example, near-infrared light, visible light, and ultraviolet light emitting devices that use silicon nano-size dots, have new structures that overcome a limit of silicon semiconductor, namely, a low luminous efficiency caused by indirect transition. Silicon light emitting devices have been actively researched because they are easily compatible with other silicon-based photoelectronic devices and are manufactured at low costs. However, silicon light emitting devices are still unsuitable for electronic apparatuses because of low luminous efficiency and have several characteristics that need to be improved. Recently, some efforts are made to increase the low luminous efficiency by using a doped layer or reducing the thickness of an active layer.

A conventional light emitting device is usually larger than 300 μm×300 μm in size. The luminous efficiency of such a conventional large-area light emitting device can be further increased through several improvements. These improvements may significantly advance the commercialization of silicon light emitting devices.

In conventional nitride semiconductor micro light-emitting devices, a micrometer-sized structure has a cylindrical shape, leading an effective increase in light extraction to the outside. However, some of the light emitted through the lateral side of the micrometer-sized structure may be unnecessarily lost due to diffusion or the like. Hence, the actual brightnesses of conventional light-emitting devices do not greatly increase in spite of the increase of the light extraction to the outside, because it is general that the brightness of a light emitting device depends on the total amount of light emitted to the front side of the light emitting device. Therefore, the total amount of light emitted to the front side of a light emitting device is important.

### DISCLOSURE OF INVENTION

### Technical Problem

The present invention provides a highly-efficient silicon light emitting device including an improved structure by which more light of the light emitted toward the lateral side of the light emitting device is emitted toward the front side thereof than conventional light emitting devices so as to improve the brightness.

### Technical Solution

According to an aspect of the present invention, there is provided a silicon light emitting device including: a substrate; a plurality of light emitting structures formed on the substrate, each of the light emitting structures comprising an active layer; and a metal electrode comprising a lower metal electrode formed below the substrate and an upper metal electrode formed on the light emitting structures, wherein the light emitting structures have column shapes whose vertical cross-sections are inverse trapezoid.

According to an embodiment of the present invention, the doped layers may be formed of either silicon carbon nitride (SiCₓN₁₋ₓ, 0≦x≦1) or silicon carbide (SiₓC₁₋ₓ, 0≦x≦1). The doped layers may be a p-type doped layer formed on the lower surface of the active layer and an n-type doped layer formed on the upper surface of the active layer.

Lateral sides of the light emitting structures may be covered by an insulation layer formed of silicon oxide or silicon nitride. The silicon light emitting device may further include a transparent electrode layer formed on upper surfaces of the n-type doped layer and the insulation layer. The upper metal electrode may be formed on a portion of an upper surface of the transparent electrode layer.

The active layer may have crystalline silicon nano-sized dots or amorphous silicon nano-sized dots.

According to another aspect of the present invention, there is provided a silicon light emitting device including: a substrate; a light emitting structure formed on the substrate and comprising an active layer; a plurality of insulation layers formed by etching the light emitting structure to have columns whose vertical cross-sections are trapezoid and filling the etched-out portions with an insulative material, the etching being performed until the substrate is exposed; and a metal electrode comprising a lower metal electrode formed below the substrate and an upper metal electrode formed on the light emitting structure, wherein a cross-section of a portion of the light emitting structure defined by adjacent insulation layers is vertically inverse trapezoid.

According to an embodiment of the present invention, each of the insulation layers is designed to have a trapezoid vertical cross-section so that the portions of the light emitting structure between adjacent insulation layers have inverse-trapezoid vertical cross-sections. The silicon light emitting device may further include a transparent electrode layer formed on upper surfaces of the light emitting structure and the insulation layers. The upper metal electrode may be formed on a portion of an upper surface of the transparent electrode layer.

According to an embodiment of the present invention, the silicon light emitting device may further include a transparent electrode layer formed on an upper surface of the light emitting structure. The insulation layers may be formed by etching the light emitting structure and the transparent electrode layer. The upper metal electrode may be formed on the transparent electrode layer.

### Advantageous Effects

A highly efficient light emitting device according to the present invention includes a plurality of micro-sized light emitting structures having inverse-trapezoid vertical cross-sections. Thus, the amount of light emitted toward the front side of the device is increased, and the luminous efficiency is improved.

In addition, a transparent electrode layer may be formed over all of the light emitting structures, so that when an external voltage is applied to the transparent electrode layer, the light emitting structures emit light at the same time. Therefore, the highly efficient silicon light emitting device according to the present invention provides much higher optical output than a conventional large-area light emitting device having the same area.

### DESCRIPTION OF DRAWINGS

The above and other features and advantages of the present invention will become more apparent by describing in detail exemplary embodiments thereof with reference to the attached drawings in which:

FIG. 1A is a perspective view of a highly efficient silicon light emitting device according to an embodiment of the present invention;

FIG. 1B is a cross-section taken along line I-I of FIG. 1A;

FIG. 2A is a perspective view of a highly efficient silicon light emitting device according to another embodiment of the present invention;

FIG. 2B is a cross-section taken along line II-II of FIG. 2A;

FIG. 3 is a cross-sectional view of a highly-efficient silicon light emitting device according to another embodiment of the present invention; and

FIG. 4 is a graph showing a comparison between the optical efficiency of the highly efficient silicon light emitting device shown in FIGS. 1A and 1B and that of a conventional large-area light emitting device.

### BEST MODE

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses or sizes of layers and regions are exaggerated for clarity. It will also be understood that when an element is referred to as being ‘on’ another element, it can be directly on the other element, or intervening elements may also be present. Like reference numerals in the drawings denote like elements, and thus their description will be omitted.

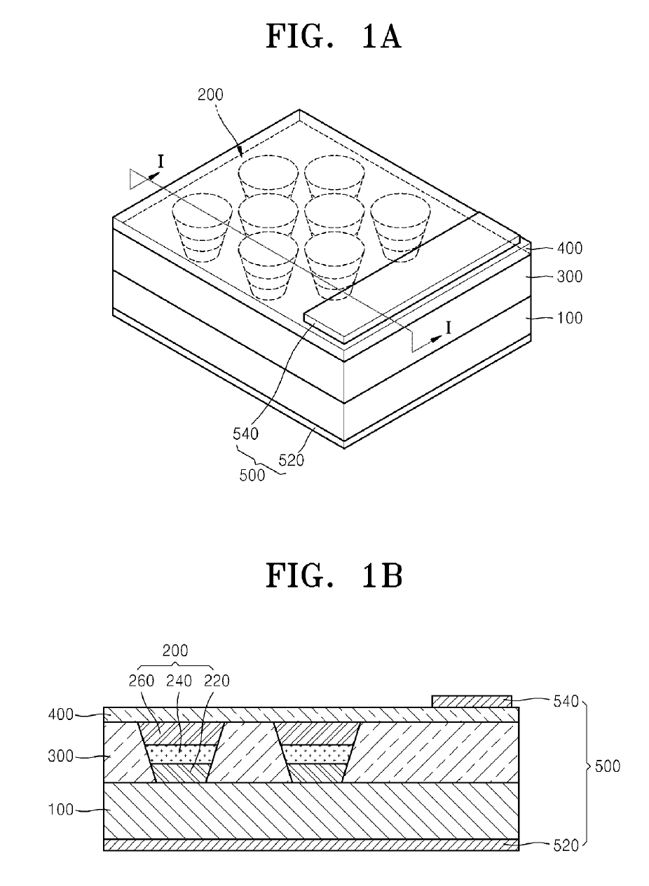

FIG. 1A is a perspective view of a highly efficient silicon light emitting device according to an embodiment of the present invention. Referring to FIG. 1A, the highly-efficient silicon light emitting device includes a substrate 100, a plurality of light emitting structures 200 formed on the substrate 100, an insulation layer 300 formed on the substrate 100 and surrounding lateral surfaces of the light emitting structures 200, a transparent electrode layer 400 formed on the light emitting structures 200 and the insulation layer 300, and a metal electrode 500 for applying voltage to the light emitting structures 200.

A p-type silicon substrate is generally used as the substrate 100. Each of the light emitting structures 200 has a cylindrical shape whose vertical cross-section is inverse trapezoid, so as to prevent light emitting through the lateral surface of the light emitting structure 200 from being lost due to diffusion or the like. Although the light emitting structures 200 having cylindrical shapes are illustrated in the embodiment of FIG. 1A, the light emitting structures 200 may have elliptical cylindrical shapes as long as their vertical cross-sections are inverse trapezoid.

The insulation layer 300 may be formed of silicon oxide or silicon nitride and surrounds the lateral surfaces of the light emitting structures 200. the transparent electrode layer 400 may be formed of ITO or InₓZn₁₋ₓO(0≦x≦1) and applies current to all of the light emitting structures 200.

The metal electrode 500 includes a lower metal electrode 520 formed on the bottom surface of the substrate 100 and an upper metal electrode 540 formed on a portion of the top surface of the transparent electrode layer 400. The upper metal electrode 540 applies voltage to the entire area of the transparent electrode layer 400.

In the embodiment of FIG. 1A, the transparent electrode layer 400 is formed over all of the light emitting structures 200 so as to apply voltage to all of the light emitting structures 200 at the same time. However, the transparent electrode layer 400 or the upper metal electrode 540 may be patterned and connected to the light emitting structures 200 so that voltages are applied to the light emitting structures 200 individually.

FIG. 1B is a cross-section taken along line I-I of FIG. 1A. The structure and components of the light emitting structures 200 will now be described in greater detail.

Referring to FIG. 1B, the silicon light emitting device is constructed by sequentially forming the lower metal electrode 520, the substrate 100, the light emitting structures 200, the insulation layer 300, the transparent electrode layer 400, and the upper metal electrode 540.

As described above, the vertical cross-sections of the light emitting structures 200 are inverse trapezoid. Each of the light emitting structures 200 includes an active layer 240, which is a light emitting region, a p-type doped layer 220 formed below the active layer 240, and an n-type doped layer 260 formed above the active layer 240. the doped layers 220 and 260 are formed of silicon carbon nitride (SiCₓN₁₋ₓ, 0≦x≦1) or silicon carbide (SiₓC₁₋ₓ, 0≦x≦1) to have doping concentrations of about 10¹⁶˜10¹⁹ [symbol] and thicknesses of about 0.1˜1 [symbol] . The doping concentrations and the thicknesses may vary according to the characteristics of a light emitting device.

The active layer 240 may have crystalline silicon nano-sized dots or amorphous silicon nano-sized dots. The active layer 240 may have a thickness of about 10 [symbol] ˜100 [symbol] .

The top surfaces of the light emitting structures 200, namely, the top surfaces of the n-type doped layers 260, may have diameters of about 30 [symbol] or less. To have inverse-trapezoid vertical cross-sections, the bottom surfaces of the light emitting structures 200 may have diameters smaller than the top surfaces. Of course, the sizes of the light emitting structures 200 may vary according to the characteristics of a light emitting device.

In a brief description of a method of forming the highly-efficient light emitting device shown in FIGS. 1A and 1B, the p-type doped layer 220, the active layer 240 having silicon nano-sized dots, and the n-type doped layer 260 are formed on the p-type silicon substrate 100. Thereafter, the p-type doped layer 220, the active layer 240, and the n-type doped layer 260 are dry-etched to have an inverse-trapezoid vertical cross-section, thereby forming each of the light emitting structures 200.

The light emitting structures 200 having inverse-trapezoid vertical cross-sections have lateral surfaces that are not vertical but inclined. Hence, when light produced in the active layer 240 is emitted through the lateral surface, the path of the light is changed to the top surface of the light emitting device, so that disappearance of light due to diffusion can be reduced. Hence, the highly efficient light emitting device having improved luminous efficiency can be obtained.

After the formation of the light emitting structures 200, the empty spaces between the light emitting structures 200 are filled with a silicon oxide insulator according to a plasma enhanced chemical vapor deposition (PECVD) method, whereby the insulation layer 300 is formed. The transparent electrode layer 400 is formed of ITO on the light emitting structures 200 and the insulation layer 300 by sputtering. Finally, the lower metal electrode 520 and the upper metal electrode 540 are deposited on the resultant structure, thereby completing the formation of the highly efficient silicon light emitting device.

In the highly-efficient silicon light emitting device according to the present embodiment, the plurality of light-emitting structures 200 have inverse trapezoid vertical cross-sections, so that light produced in the active layers 260 are easily emitted toward the front side of the light emitting device. Therefore, the highly efficient silicon light emitting device outputs more light than a conventional large-area light emitting device having the same area.

In addition, current applied to each of the light emitting structures 200 moves from a wider area to a narrower area, so that unnecessary current leakage is reduced. This results in a more effective use of current, so that the light emitting device according to the present embodiment provides increased quantum efficiency.

Furthermore, the light emitting structures 200 are all connected to both the silicon substrate 100 formed therebelow and the transparent electrode layer 400 formed thereon. Accordingly, when an external voltage is applied to the lower metal electrode 520 and the upper metal electrode 540, all of the light emitting structures 200 emit light at the same time. Therefore, the highly-efficient large silicon light emitting device according to the present embodiment provide much higher brightness than a conventional large-area light emitting device having the same area.

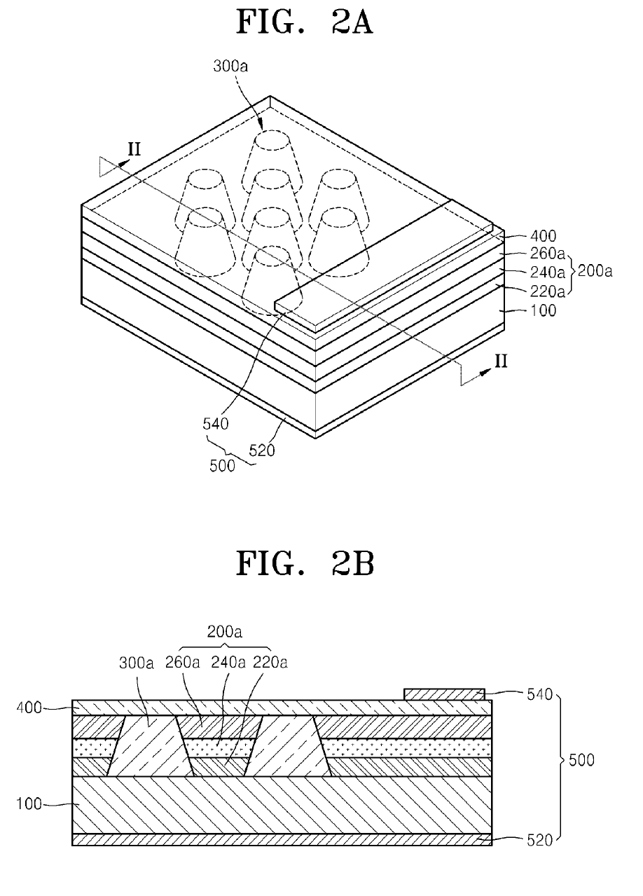

FIG. 2A is a perspective view of a highly efficient silicon light emitting device according to another embodiment of the present invention. Referring to FIG. 2A, the highly-efficient silicon light emitting device includes the substrate 100, a light emitting structure 200a, a plurality of insulation layers 300a formed in the light emitting structure 200a and each having a trapezoid vertical cross-section, a transparent electrode layer 400 formed on the light emitting structure 200a and the insulation layers 300a, and the metal electrode 500.

In the highly-efficient silicon light emitting device shown in FIG. 2A, the insulation layers 300a each having a trapezoid vertical cross-section are formed in the light emitting structure 200a, so that portions of the light emitting structure 200a defined by adjacent insulation layers 300a have inverse-trapezoid vertical cross-sections, as in the embodiment of FIGS. 1A and 1B. However, in contrast with the embodiment of FIGS. 1A and 1B, the light emitting structure 200a is formed to be one body.

In the embodiment of FIG. 2A, a p-type doped layer 220a, an active layer 240a having silicon nano-sized dots, and an n-type doped layer 260a are formed on the substrate 100. Thereafter, the p-type doped layer 220a, the active layer 240a, and the n-type doped layer 260a are etched to have trapezoid vertical cross-sections. The empty spaces resulting from the etching are filled with an insulator to thereby form the insulation layers 300a. The other elements are the same as those in the embodiment of FIGS. 1A and 1B.

FIG. 2B is a cross-section taken along line II-II of FIG. 2A. The cross-section of FIG. 2B is almost the same as that of FIG. 1B.

The insulation layers 300a should be designed so that the portions of the light emitting structure 200a between adjacent insulation layers 300a have inverse-trapezoid vertical cross-sections. More specifically, the top surface of each of the portions of the light emitting structure 200a may have a diameter of about 30 μm or less, and the bottom surface of each of the portions of the insulation layer 300a may have a diameter smaller than the diameter of the top surface. In other words, the bottom surface of each of the portions of the light emitting structure 200a may have a diameter of about 30 μm or less, and the top surface of each of the portions of the insulation layer 300a may have a diameter smaller than the diameter of the bottom surface, whereby a light emitting structure 200a having a desirable size can be formed. Of course, the gap between adjacent insulation layers 300a should be suitably adjusted in a three-dimensional fashion.

The characteristics, such as, the materials or thicknesses, of the substrate 100, the p-type doped layer 220a, the active layer 240a, and the n-type doped layer 260a, the insulation layers 300a, and the transparent electrode layer 400 are the same as described in the embodiment of FIGS. 1A and 1B.

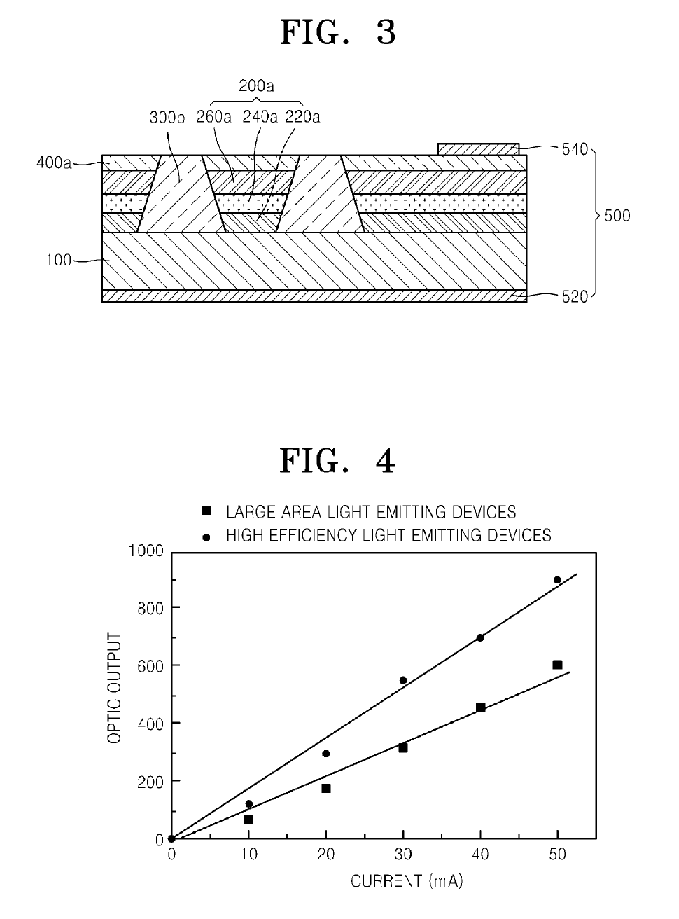

FIG. 3 is a cross-sectional view of a highly efficient silicon light emitting device according to another embodiment of the present invention. The highly efficient silicon light emitting device is similar to the embodiment of FIGS. 2A and 2B except for a transparent electrode layer 400a. More specifically, insulation layers 300b extend up to the transparent electrode layer 400a above the light emitting structure 200a. The light emitting structure 200a and the transparent electrode layer 400a are etched together so that the insulation layers 300b have trapezoid vertical cross-sections. Although the transparent electrode layer 400a is partitioned as viewed from the cross-section of FIG. 3, it is one body as seen from the three-dimensional point of view.

The light emitting structure 200a in this embodiment has the same structure as that according to the embodiment of FIGS. 2A and 2B. The characteristics, such as, the materials or thicknesses, of the substrate 100, the p-type doped layer 220a, the active layer 240a, and the n-type doped layer 260a, the insulation layers 300b, and the transparent electrode layer 400a are the same as described in the embodiment of FIGS. 1A and 1B.

FIG. 4 is a graph showing a comparison between the optical efficiencies of the highly efficient silicon light emitting device shown in FIGS. 1A and 1B and a conventional large-area light emitting device. Referring to FIG. 4, the horizontal axis indicates current (unit: mA) applied to the light emitting devices, and the vertical axis indicates light outputs expressed in relative values. Accordingly, the unit in which a light output is represented is not needed. As shown in FIG. 4, the difference between the optical outputs of the highly efficient silicon light emitting device shown in FIGS. 1A and 1B and the conventional large-area light emitting device increases as the current increases.

As described above, a highly efficient light emitting device according to the present invention includes a plurality of micro-sized light emitting structures having inverse-trapezoid vertical cross-sections. Thus, the amount of light emitted toward the front side of the device is increased, and the luminous efficiency is improved.

In addition, a transparent electrode layer may be formed over all of the light emitting structures, so that when an external voltage is applied to the transparent electrode layer, the light emitting structures emit light at the same time. Therefore, the highly efficient silicon light emitting device according to the present invention provides much higher optical output than a conventional large-area light emitting device having the same area.

While the present invention has been particularly shown and described with reference to exemplary embodiments thereof, it will be understood by those of ordinary skill in the art that various changes in form and details may be made therein without departing from the spirit and scope of the present invention as defined by the following claims.

### INDUSTRIAL APPLICABILITY

The present invention relates to a silicon light emitting device which uses a silicon fine structure as an active layer and has a new structure that is capable of increasing the optical extraction efficiency. A highly efficient light emitting device according to the present invention provides much higher optical output than a conventional large-area light emitting device having the same area.

1. A silicon light emitting device comprising:
a substrate;
a plurality of light emitting structures formed on the substrate, each of the light emitting structures comprising an active layer; and
a metal electrode comprising a lower metal electrode formed below the substrate and an upper metal electrode formed on the light emitting structures,
wherein the light emitting structures have column shapes whose vertical cross-sections are inverse trapezoid.

2. The silicon light emitting device of claim 1, wherein each of the light emitting structures comprises at least one doped layer that is formed on an upper surface or lower surface of the active layer.

3. The silicon light emitting device of claim 2, wherein the doped layers are a p-type doped layer formed on the lower surface of the active layer and an n-type doped layer formed on the upper surface of the active layer.

4. The silicon light emitting device of claim 3, wherein:
lateral sides of the light emitting structures are covered by an insulation layer formed of one material of silicon oxide and silicon nitride; and
the upper metal electrode is formed on an upper surface of the n-type doped layer.

5. The silicon light emitting device of claim 3, wherein:
lateral sides of the light emitting structures are covered by an insulation layer formed of one material of silicon oxide and silicon nitride;
the silicon light emitting device further comprises a transparent electrode layer formed on upper surfaces of the n-type doped layer and the insulation layer; and
the upper metal electrode is formed on a portion of an upper surface of the transparent electrode layer.

6. The silicon light emitting device of claim 5, wherein the transparent electrode layer is formed of one material of ITO and InₓZn₁₋ₓO(0≦x≦1).

7. The silicon light emitting device of claim 2, wherein the doped layers are formed of one material of silicon carbon nitride (SiCₓN₁₋ₓ, 0≦x≦1) and silicon carbide(SiₓC₁₋ₓ, 0≦x≦1).

8. The silicon light emitting device of claim 7, wherein the doped layers are a p-type doped layer formed on the lower surface of the active layer and an n-type doped layer formed on the upper surface of the active layer.

9. The silicon light emitting device of claim 1, wherein the active layer has one selected from crystalline silicon nano-sized dots and amorphous silicon nano-sized dots.

10. The silicon light emitting device of claim 1, wherein:
each of the light emitting structures has a circular cylindrical shape; and
the top surface of each of the light emitting structures has a diameter of about 30 [symbol] or less, and the bottom surface of each of the light emitting structures has a diameter smaller than the top surface.

11. A silicon light emitting device comprising:
a substrate;
a light emitting structure formed on the substrate and comprising an active layer;
a plurality of insulation layers formed by etching the light emitting structure to have columns whose vertical cross-sections are trapezoid and filling the etched-out portions with an insulative material, wherein the etching is performed until the substrate is exposed; and
a metal electrode comprising a lower metal electrode formed below the substrate and an upper metal electrode formed on the light emitting structure,
wherein a cross-section of a portion of the light emitting structure defined by adjacent insulation layers is vertically inverse trapezoid.

12. The silicon light emitting device of claim 11, wherein:
each of the insulation layers has a circular cylindrical shape;
the bottom surface of each of the insulation layers has a diameter of about 30 [symbol] or less, and the top surface of each of the insulation layers has a diameter smaller than the diameter of the top surface; and
the length of the upper side of the inverse-trapezoid vertical cross-section of the portion of the light emitting structure by adjacent insulation layers is equal to the diameter of the bottom surface of each of the insulation layers.

13. The silicon light emitting device of claim 11, wherein the light emitting structure comprises at least one doped layer that is formed on an upper surface or lower surface of the active layer.

14. The silicon light emitting device of claim 13, wherein:
the doped layers are formed of one material of silicon carbon nitride (SiCₓN₁₋ₓ, 0≦x≦1) and silicon carbide (SiₓC₁₋ₓ, 0≦x≦1); and
the doped layers are a p-type doped layer formed on the lower surface of the active layer and an n-type doped layer formed on the upper surface of the active layer.

15. The silicon light emitting device of claim 11, further comprising a transparent electrode layer formed on upper surfaces of the light emitting structure and the insulation layers,
wherein the upper metal electrode is formed on a portion of an upper surface of the transparent electrode layer.

16. The silicon light emitting device of claim 11, further comprising a transparent electrode layer formed on an upper surface of the light emitting structure, wherein:
the insulation layers are formed by etching the light emitting structure and the transparent electrode layer; and
the upper metal electrode is formed on the transparent electrode layer.

17. The silicon light emitting device of claim 11, wherein the active layer has one selected from crystalline silicon nano-sized dots and amorphous silicon nano-sized dots.
